(19) United States
(12) Patent Application Publication
(10) Pub. No.: US 2021/0384017 A1
(43) Pub. Date: Dec. 9, 2021

(54) TRAP APPARATUS AND SUBSTRATE PROCESSING APPARATUS

(71) Applicant: Tokyo Electron Limited, Tokyo (JP)

(72) Inventors: Takaaki NEZU, Miyagi (JP); Yuta YAMATO, Miyagi (JP); Akiyoshi KAWASHIMA, Koshi City (JP); Hiroki INADUMA, Miyagi (JP); Kazuyuki MIURA, Miyagi (JP)

(21) Appl. No.: 17/336,890

(22) Filed: Jun. 2, 2021

(30) Foreign Application Priority Data
Jun. 3, 2020 (JP) 2020-097165

(51) Int. Cl. H01J 37/32

(52) U.S. Cl. CPC H01J 37/32871; H01J 37/32834; H01J 37/32449

(57) ABSTRACT

The present invention efficiently captures a target object contained in an exhaust gas. A trap apparatus includes a tubular housing including a flow path through which an exhaust gas exhausted through an exhaust pipe flows, a plate-shaped first trap member arranged inside the housing so as to shield a central portion of the flow path when viewed in a direction along a central axis of the housing, and a plate-shaped second trap member arranged inside the housing at an interval from the first trap member in the direction along the central axis of the housing, the second trap member including an opening at a position corresponding to the first trap member.

### CROSS-REFERENCE TO RELATED APPLICATION

This application is based upon and claims the benefit of priority from Japanese Patent Application No. 2020-097165, filed on Jun. 3, 2020, the entire contents of which are incorporated herein by reference.

### TECHNICAL FIELD

The present disclosure relates to a trap apparatus and a substrate processing apparatus.

### BACKGROUND

Patent Document 1 discloses a technique in which a housing configured to accommodate a two-stage trap therein is provided in an exhaust pipe connected to a processing container in which substrate processing is performed, and byproducts contained in an exhaust gas exhausted through the exhaust pipe are captured as a target object using the two-stage trap.

### PRIOR ART DOCUMENT

### [Patent Document]

Patent Document 1: Japanese Laid-Open Patent Publication No. 2015-80738

### SUMMARY

According to one embodiment of the present disclosure, a trap apparatus includes a tubular housing including a flow path through which an exhaust gas exhausted through an exhaust pipe flows, a plate-shaped first trap member arranged inside the housing so as to shield a central portion of the flow path when viewed in a direction along a central axis of the housing, and a plate-shaped second trap member arranged inside the housing at an interval from the first trap member in the direction along the central axis of the housing, the second trap member including an opening at a position corresponding to the first trap member.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical cross-sectional view schematically illustrating a configuration of a substrate processing apparatus according to an embodiment.

FIG. 2 is a perspective cross-sectional view illustrating an exemplary trap apparatus according to the embodiment.

FIG. 3 is a top view illustrating a first trap member and a second trap member according to an embodiment as viewed in a direction along a central axis of a housing.

FIG. 4 is a view illustrating an exemplary flow of an exhaust gas in a flow path of a trap apparatus according to an embodiment.

FIG. 5 is a view illustrating another exemplary configuration of the trap apparatus according to an embodiment.

FIG. 6 is a top view of a first trap member and a second trap member illustrated in FIG. 5 as viewed in a direction along a central axis of a housing.

### DETAILED DESCRIPTION

Reference will now be made in detail to various embodiments, examples of which are illustrated in the accompanying drawings. In the following detailed description, numerous specific details are set forth in order to provide thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a trap apparatus and a substrate processing apparatus disclosed herein will be described in detail with reference to the drawings. In each drawing, the same or corresponding components will be denoted by the same reference numerals. The processing apparatus disclosed herein is not limited by the embodiments.

In the meanwhile, there may be room for improvement in the technique of capturing byproducts contained in an exhaust gas exhausted through an exhaust pipe using a two-stage trap.

Therefore, it is expected that a target object contained in the gas exhausted through the exhaust pipe can be efficiently captured.

### EMBODIMENT

### [Configuration of Substrate Processing Apparatus]

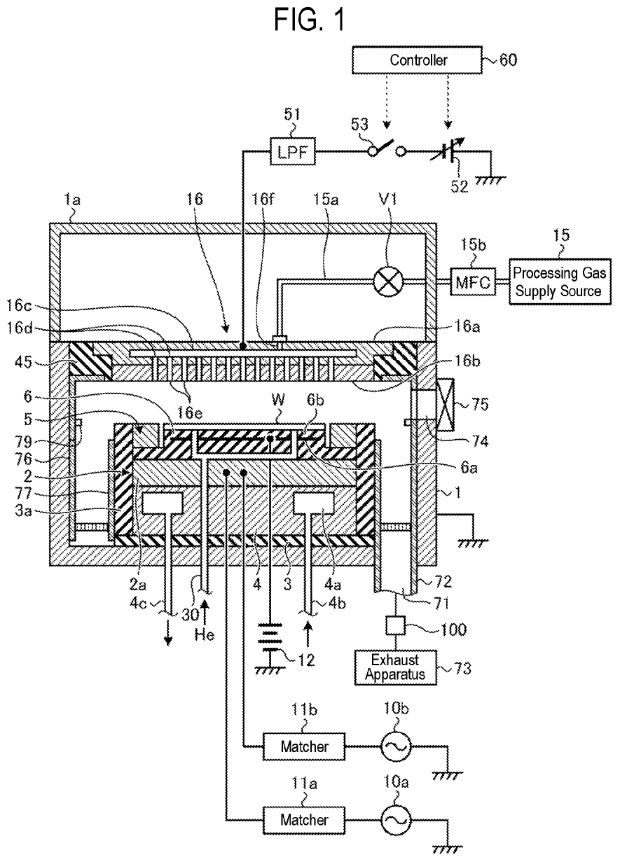

FIG. 1 is a vertical cross-sectional view schematically illustrating a configuration of a substrate processing apparatus according to an embodiment. The substrate processing apparatus illustrated in FIG. 1 is a parallel plate-type plasma processing apparatus, and has a processing container 1, which is configured to be hermetically sealed and is electrically grounded. The processing container 1 has a cylindrical shape and is made of, for example, aluminum or the like, and defines a plasma processing space for performing plasma processing such as plasma etching. In the processing container 1, a stage 2 on which a semiconductor wafer (hereinafter, referred to as “wafer”) W as a substrate to be processed is placed, is provided. The stage 2 has a base 2a and an electrostatic chuck (ESC) 6. The base 2a is made of a conductive metal (e.g., aluminum), and has a function as a lower electrode. The electrostatic chuck 6 provides a function of electrostatically attracting the wafer W. The stage 2 is supported on a conductor support 4 with an insulating plate 3 lying underneath. Further, a focus ring 5 made of, for example, single-crystal silicon, is provided on the upper outer periphery of the stage 2. In addition, in the processing container 1, a cylindrical inner wall member 3a made of, for example, quartz, is provided so as to surround the periphery of the stage 2 and the support 4.

The base 2a is connected to a first RF power supply 10a via a first matcher 11a. In addition, a second RF power supply 10b is connected to the base 2a via a second matcher 11b. The first RF power supply 10a is a power source for plasma generation. From the first RF power supply 10a, high-frequency power having a predetermined frequency (27 MHz or higher, for example, 40 MHz) is supplied to the base 2a of the stage 2. Further, the second RF power supply 10b is a power supply for ion attraction (for bias). From the second RF power supply 10b, high-frequency power having a predetermined frequency (13.56 MHz or lower, for example, 3.2 MHz) lower than that of the first RF power supply 10a is supplied to the base 2a of the stage 2.

An upper electrode 16 is provided above the stage 2 so as to face the stage 2, with a plasma processing space in the processing container 1 interposed therebetween. The upper electrode 16 and the stage 2 function as a pair of electrodes. A space between the upper electrode 16 and the stage 2 serves as the plasma processing space for generating plasma.

The electrostatic chuck 6 is configured with an electrode 6a interposed between insulators 6b, and a DC power supply 12 is connected to the electrode 6a. The electrostatic chuck 6 is configured to attract a semiconductor wafer W using Coulomb force when a DC voltage from the DC power supply 12 is applied to the electrode 6a.

A coolant flow path 4a is formed inside the support 4, and a coolant inlet pipe 4b and a coolant outlet pipe 4c are connected to the coolant flow path 4a. The support 4 and the stage 2 are configured to be controllable to a predetermined temperature by circulating an appropriate coolant (e.g., cooling water) in the coolant flow path 4a. In addition, a backside gas supply pipe 30 configured to supply a cold heat transfer gas (a backside gas), such as a helium gas, to a rear surface side of the wafer W is provided so as to penetrate the stage 2 and the like. The backside gas supply pipe 30 is connected to a backside gas supply source (not illustrated). With this configuration, it is possible to control the wafer W placed on the top surface of the stage 2 to a predetermined temperature.

The upper electrode 16 is provided on a ceiling wall portion of the processing container 1. The upper electrode 16 includes a main body 16a and an upper ceiling plate 16b forming an electrode plate, and is supported on an upper portion of the processing container 1 by disposing an insulating member 45. The main body 16a is made of a conductive material (e.g., aluminum having an anodized surface), and is configured to detachably support the upper ceiling plate 16b underneath.

A gas diffusion chamber 16c is provided inside the main body 16a. A plurality of gas flow holes 16d are formed in a bottom portion of the main body 16a so as to be located below the gas diffusion chamber 16c. The upper ceiling plate 16b includes gas introduction holes 16e penetrating the upper ceiling plate 16b in a thickness direction thereof and provided to overlap the gas flow holes 16d described above. A processing gas supplied to the gas diffusion chamber 16c is diffused in a form of shower, and is supplied into the processing container 1 through the gas flow holes 16d and the gas introduction holes 16e. Further, the main body 16a and the like are provided with a pipe (not illustrated) so as to circulate the coolant so that it is possible to cool the upper electrode 16 to a desired temperature during a plasma etching process.

The main body 16a has a gas introduction port 16f formed to introduce a processing gas into the gas diffusion chamber 16c. One end of a gas supply pipe 15a is connected to the gas introduction port 16f. A processing gas supply source 15 is connected to the other end of the gas supply pipe 15a so as to supply a processing gas for etching. The gas supply pipe 15a is provided from an upstream side in an order of a mass flow controller (MFC) 15b and an opening and closing valve V1. The processing gas for plasma etching is supplied from the processing gas supply source 15 to the gas diffusion chamber 16c through the gas supply pipe 15a, and from the gas diffusion chamber 16c, the processing gas is diffused and supplied into the processing container 1 in the form of shower through the gas flow holes 16d and the gas introduction holes 16e.

A variable DC power supply 52 is electrically connected to the upper electrode 16 via a low-pass filter (LPF) 51. Power feeding from the variable DC power supply 52 can be turned on and off by an on and off switch 53. The current and voltage of the variable DC power supply 52 and the on and off of the on and off switch 53 are controlled by a controller 60 to be described later. As will be described later, when high-frequency waves are applied to the stage 2 from the first RF power supply 10a and the second RF power supply 10b and plasma is generated in the plasma processing space, the on and off switch 53 is turned on by the controller 60 as needed, and a predetermined DC voltage is applied to the upper electrode 16.

A cylindrical ground conductor la is provided so as to extend from a side wall of the processing container 1 to a position above a height position of the upper electrode 16. The ground conductor la has a ceiling wall in an upper portion thereof.

An exhaust port 71 is formed in a bottom portion of the processing container 1. An exhaust apparatus 73 is connected to the exhaust port 71 through an exhaust pipe 72. The exhaust pipe 72 interconnects the processing container 1 and the exhaust apparatus 73. The exhaust apparatus 73 has a vacuum pump, and by operating the vacuum pump, a gas is exhausted from the processing container 1 through the exhaust pipe 72. The gas exhausted from the processing container 1 through the exhaust pipe 72 includes byproducts generated by substrate processing (e.g., plasma processing) in the processing container 1.

The exhaust pipe 72 is provided with a trap apparatus 100 configured to capture a target object (byproducts) contained in the gas exhausted from the processing container 1 through the exhaust pipe 72. The detailed configuration of the trap apparatus 100 will be described later.

A wafer W loading and unloading port 74 is provided in the side wall of the processing container 1. A gate valve 75 is provided in the loading and unloading port 74 so as to open and close the loading and unloading port 74.

Deposit shields 76 and 77 are detachably provided on an inner wall surface of the processing container 1. The deposit shields 76 and 77 serve to prevent etching byproducts (deposits) from adhering to the processing container 1. A DC grounded conductive member (a GND block) 79 is provided on the deposit shield 76 at substantially the same height position as the wafer W, thereby preventing abnormal discharge.

Operations of the substrate processing apparatus having the configuration described above is controlled overall by the controller 60. The controller 60 is provided with a process controller including a CPU so as to control each part of the substrate processing apparatus, a user interface, and a storage.

The user interface of the controller 60 includes, for example, a keyboard on which a process manager performs a command input operation in order to manage the plasma etching apparatus, and a display configured to visualize and display operation status of the plasma etching apparatus.

The storage of the controller 60 stores, for example, a control program (software) for implementing various processes executed in the substrate processing apparatus under the control of the process controller, and a recipe storing processing condition data or the like. An arbitrary recipe is called from the storage by an instruction from the user interface of the controller 60 and executed at the process controller, whereby a desired process in the substrate processing apparatus is performed under the control of the process controller of the controller 60. A control program or a recipe such as processing condition data may be used in a state of being stored in a computer-readable computer storage medium (e.g., a hard disk, a CD, a flexible disk, a semiconductor memory, or the like). Alternatively, a control program or a recipe such as processing condition data may be transmitted from another device at any time via, for example, a dedicated transmission line, so as to be used online.

### [Configuration of Trap Apparatus 100]

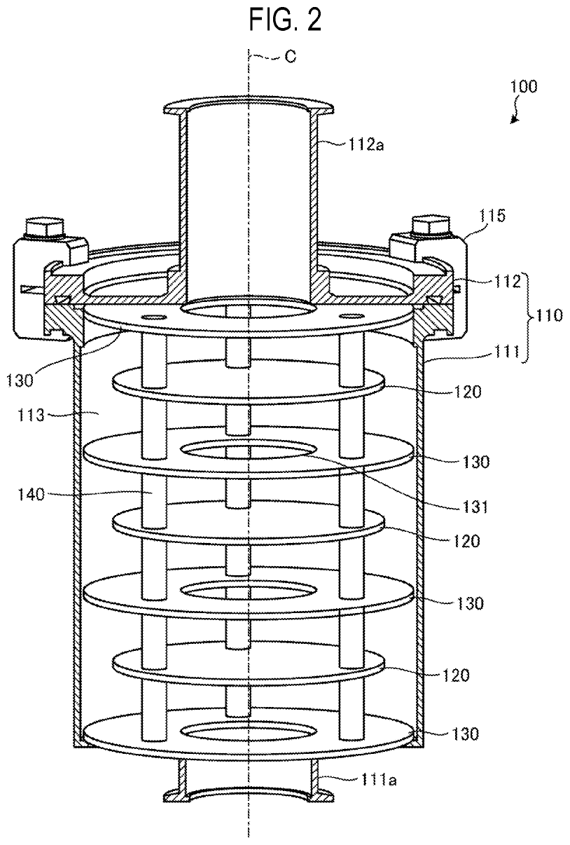

Next, detailed configuration of the trap apparatus 100 provided in the exhaust pipe 72 will be described. FIG. 2 is a perspective cross-sectional view illustrating an exemplary trap apparatus 100 according to the embodiment. In the following description, the exhaust pipe 72 located closer to the exhaust port 71 of the processing container 1 than the trap apparatus 100 will be referred to as an “upstream side exhaust pipe 72,” and an exhaust pipe 72 located closer to the exhaust apparatus 73 than the trap apparatus 100 will be referred to as a “downstream side exhaust pipe 72.”

The trap apparatus 100 illustrated in FIG. 2 has a housing 110, a plurality of first trap members 120, and a plurality of second trap members 130. The plurality of first trap members 120 and the plurality of second trap members 130 are alternately arranged in a direction along a central axis C of the housing 110. In the present embodiment, three first trap members 120 and four second trap members 130 are arranged alternately by being supported by support rods 140 arranged in parallel to the direction along the central axis C of the housing 110. In the following description, when there is no particular need to distinguish, the plurality of first trap members 120 will be simply referred to as a “first trap member 120,” and the plurality of second trap members 130 will be simply referred to as a “second trap member 130.”

The housing 110 is formed in a tubular shape, and has a main body 111 and a lid 112. The main body 111 is formed in a cylinder shape with an opening in an upstream side and having a bottom, and accommodates the plurality of first trap members 120 and the plurality of second trap members 130. A joint 111a that is connected to the downstream side exhaust pipe 72 is provided in a bottom portion of the main body 111. A flange protruding outward is formed on an upper end portion of a side wall of the main body 111. The lid 112 is fixed to the flange of the main body 111 by a clamp 115 so as to close the opening of the main body 111. A joint 112a that is connected to the exhaust pipe 72 on the upstream side is provided at a center of the lid 112. In a state in which the lid 112 is fixed to the flange of the main body 111, a space created by the main body 111 and the lid 112 forms a columnar flow path 113 through which a gas exhausted from the processing container 1 through the exhaust pipe 72 (hereinafter, appropriately referred to as an “exhaust gas”) flows.

The first trap member 120 is formed in a plate shape, and is arranged in the housing 110 so as to shield a central portion of the flow path 113 when viewed in the direction along the central axis C of the housing 110. The first trap member 120 is formed in a disk shape having a plate surface perpendicular to the direction along the central axis C of the housing 110 and having a diameter smaller than that of the flow path 113. As a result, an annular gap through which the exhaust gas is capable of passing is formed between the entire circumference of a side surface of the first trap member 120 and an inner wall surface of the flow path 113.

The second trap member 130 is formed in a plate shape and is arranged in the housing 110 at an interval from the first trap member 120 in the direction along the central axis C of the flow path 113. The second trap members 130 are formed in a disk shape having a plate surface perpendicular to the direction along the central axis C of the housing 110 and having a diameter substantially equal to that of the flow path 113. Each of the second trap member 130 has an opening 131 at a position facing a corresponding one of the first trap members 120.

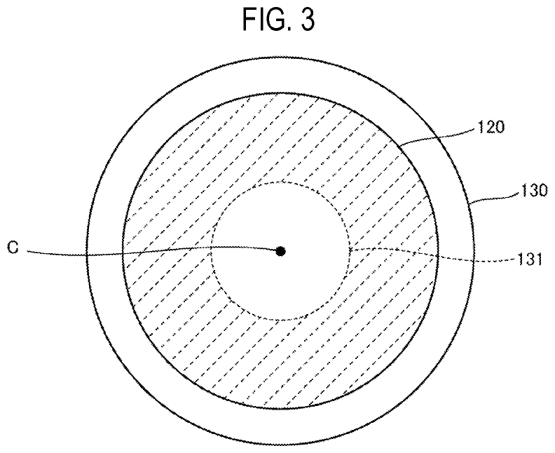

FIG. 3 is a top view illustrating a first trap member 120 and a second trap member 130 according to an embodiment when viewed in a direction along the central axis of the housing 110. The second trap member 130 has an opening 131 having an opening width smaller than a size of the first trap member 120 when viewed in the direction along the central axis C of the housing 110 at a position facing the first trap member 120. The first trap member 120 has a region that overlaps a region surrounding the opening 131 in the second trap member 130 when the first trap member 120 is viewed in the direction along the central axis C of the housing 110. That is, the first trap member 120 and the second trap member 130 overlap each other at an interval in the height direction of the housing 110 in the region surrounding the opening 131 so as to form a labyrinth structure. In FIG. 3, the region of the first trap member 120 overlapping the second trap member 130 is indicated by oblique broken lines. An exhaust gas flowing into the flow path 113 from an upstream side exhaust pipe 72 through the joint 112a passes through a bent exhaust path between the first trap member 120 and the second trap member 130, and flows out to the downstream side exhaust pipe 72 through the joint 111a.

### [Action by Trap Apparatus 100]

Next, an action of the trap apparatus 100 when performing plasma processing on a wafer W using the substrate processing apparatus illustrated in FIG. 1 will be described.

The wafer W is loaded into a processing container 1 from a loading and unloading port 74 by a transport mechanism and placed on the stage 2. In the substrate processing apparatus, inside of the processing container 1 is maintained in an appropriate pressure atmosphere by being evacuated through the exhaust pipe 72 by operating a vacuum pump of the exhaust apparatus 73.

Next, in the substrate processing apparatus, a processing gas is supplied into the processing container 1 from the processing gas supply source 15. In the substrate processing apparatus, high-frequency power from the first RF power supply 10a is applied to the stage 2 so as to plasmarize the processing gas within the processing container 1. Plasma processing, such as plasma etching, is performed on the wafer W by the plasma obtained by plasmarizing the processing gas. At this time, the substrate processing apparatus applies high-frequency power serving as high-frequency bias from the second RF power supply 10b to the stage 2, and draws ions in the plasma generated in the processing container 1 into the wafer W.

The processing gas supplied into the processing container 1 is plasmarized and provided for the plasma processing, and then suctioned by the vacuum pump of the exhaust apparatus 73.

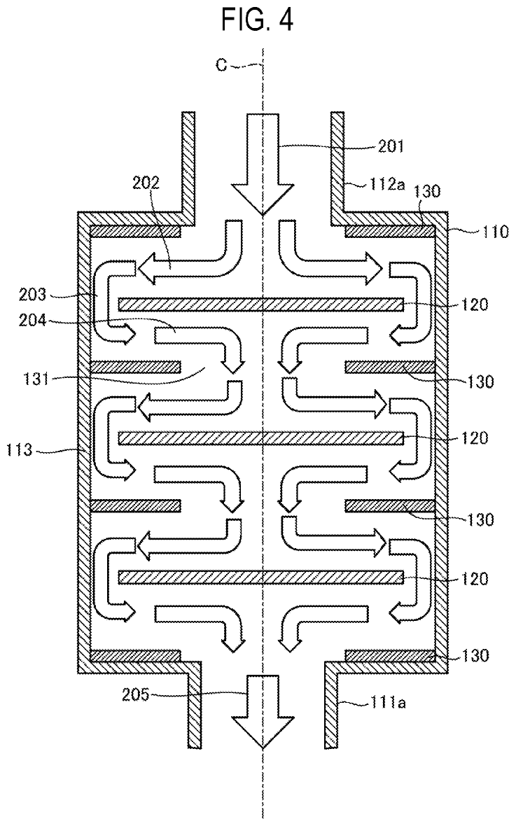

Therefore, the processing gas is exhausted as an exhaust gas from the processing container 1 through the exhaust pipe 72 provided with the trap apparatus 100. The exhaust gas contains byproducts generated by the plasma processing within the processing container 1. The exhaust gas flows from the upstream side exhaust pipe 72 into the flow path 113 of the trap apparatus 100 through the joint 112a. FIG. 4 is a view illustrating an exemplary exhaust gas flow in the flow path 113 of the trap apparatus 100 according to an embodiment. In FIG. 4, the exemplary exhaust gas flow is schematically indicated by white arrows 201 to 205. In addition, in FIG. 4, three first trap members 120 and four second trap members 130 alternately arranged in the direction along the central axis C of the housing 110 are illustrated.

The exhaust gas flowing from the upstream side exhaust pipe 72 into the flow path 113 of the trap apparatus 100 through the joint 112a passes through the opening 131 in the second trap member 130 in a first stage and reaches the first trap member 120 in the first stage, as indicated by the arrow 201. As indicated by the arrows 202, the exhaust gas that has reached the first trap member 120 in the first stage collides with the top surface of the first trap member 120 of the first stage in a central portion of the flow path 113, and is dispersed toward a peripheral edge of the flow path 113. The exhaust gas dispersed by the first trap member 120 in the first stage comes into contact with the top surface of the first trap member 120 in the first stage. As a result, since the exhaust gas is decelerated, byproducts contained in the exhaust gas are captured by the top surface of the first trap member 120 in the first stage.

The exhaust gas dispersed by the first trap member 120 in the first stage reaches an inner wall surface of the housing 110. As indicated by the arrows 203, the exhaust gas that has reached the inner wall surface of the housing 110 collides with the inner wall surface of the housing 110 and travels straight to the downstream side along the inner wall surface of the housing 110. The exhaust gas traveling straight to the downstream side along the inner wall surface of the housing 110 comes into contact with the inner wall surface of the housing 110. As a result, since the exhaust gas is decelerated, byproducts contained in the exhaust gas are captured by the inner wall surface of the housing 110.

The exhaust gas traveling straight to the downstream side along the inner wall surface of the housing 110 passes through a gap between the entire circumference of a side surface of the first trap member 120 and an inner wall surface of the flow path 113 and reaches the second trap member 130 in a second stage. The exhaust gas that has reached the second trap member 130 in the second stage collides with the top surface of the second trap member 130 in the second stage near the inner wall surface of the housing 110, as indicated by arrows 203, and is collected toward the opening 131 in the second trap member 130. The exhaust gas collected toward the opening 131 in the second trap member 130 comes into contact with a top surface of the second trap member 130. As a result, since the exhaust gas is decelerated, the byproducts contained in the exhaust gas are captured by the top surface of the second trap member 130. Then, the exhaust gas collected toward the opening 131 in the second trap member 130 passes through the opening 131 in the second trap member 130 and reaches the first trap member 120 in the second stage. Thereafter, while repeating collision and contact with top surfaces of the first trap members 120 in the second and third stages, the inner wall surface of the housing 110, and top surfaces of the second trap members 130 in the third and fourth stages, the exhaust gas reaches the joint 111a and flows out to the downstream side exhaust pipe 72.

In the trap apparatus 100 according to the present embodiment, the first trap members 120 are arranged in the housing 110 so as to shield the central portion of the flow path 113, and the second trap members 130 each having the opening 131 are arranged in the housing 110 at intervals from the first trap members 120. As a result, when passing through the bent exhaust path between the first trap members 120 and the second trap members 130, the exhaust gas repeatedly collides and comes into contact with the top surface of the first trap member 120, the inner wall surface of the housing 110, and the top surface of the second trap member 130 in each stage. As a result, the exhaust gas is decelerated stage by stage, and the byproducts contained in the exhaust gas are captured stage by stage by the top surface of the first trap member 120, the inner wall surface of the housing 110, and the top surface of the second trap member 130 in each stage. As a result, it is possible for the trap apparatus 100 to efficiently capture a target object (i.e., by-products) contained in the exhaust gas.

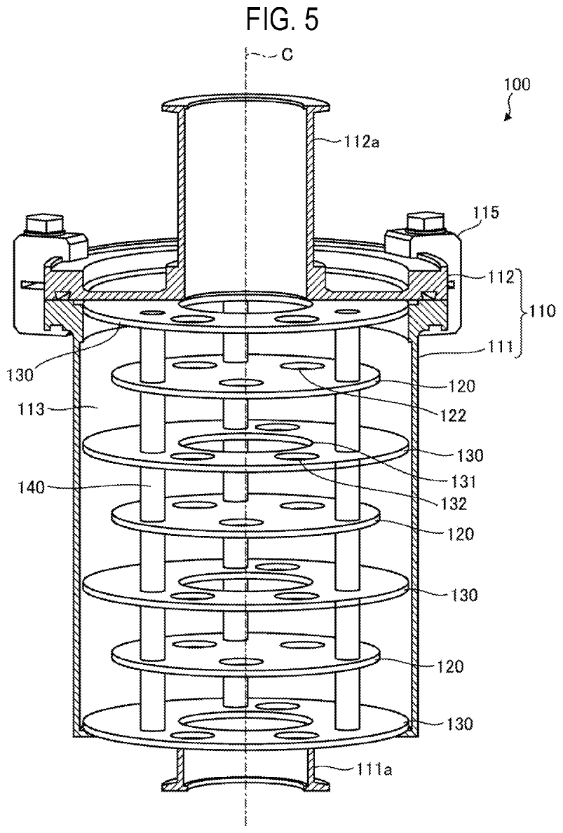

In the present embodiment, the case where the first trap members 120 have a plate shape without an opening has been described, but the present disclosure is not limited thereto. Each of the first trap members 120 may have a plurality of openings in the region overlapping the region surrounding the opening 131 in each of the second trap members 130 when viewed in the direction along the central axis C of the housing 110. In addition, each of the second trap members 130 may have a plurality of openings, which do not overlap with the plurality of openings in the first trap members 120, in the region overlapping with each of the first trap members 120 when viewed in the direction along the central axis C of the housing 110. FIG. 5 is a view illustrating another exemplary configuration of the trap apparatus 100 according to an embodiment.

Each first trap member 120 has a plurality of openings 122 formed in the region overlapping the region surrounding the opening 131 in each second trap member 130 when viewed in the direction along the central axis C of the housing 110. In the trap apparatus 100, conductance of the flow path 113 may decrease since the central portion of the flow path 113 is shielded by the first trap members 120. Therefore, in the trap apparatus 100, a plurality of openings 122 are formed in the region of each first trap member 120 overlapping the region surrounding the opening 131. Thus, the flow of the exhaust gas toward the downstream side of the first trap member 120 is promoted, and a decrease in the conductance of the flow path 113 is suppressed.

In addition, each second trap member 130 has a plurality of openings 132, which do not overlap with the plurality of openings 122 in each first trap member 120, in a region overlapping with the first trap member 120 when viewed in the direction along the central axis C of the housing 110. In the trap apparatus 100, the conductance of the flow path 113 may decrease since the flow path 113 is shielded by the second trap members 130. Therefore, in the trap apparatus 100, a plurality of openings 132, which do not overlap the plurality of openings 122, are formed in the region of each second trap member 130 overlapping the first trap members 120. Thus, the flow of exhaust gas toward the downstream side of the second trap member 130 is promoted, and a decrease in the conductance of the flow path 113 is suppressed.

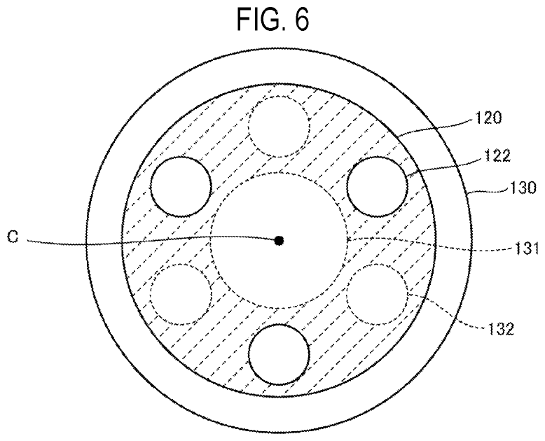

FIG. 6 is a top view illustrating a first trap member 120 and a second trap member 130 illustrated in FIG. 5 when viewed in a direction along the central axis of the housing 110. The second trap member 130 has an opening 131, at a position facing the first trap member 120, having an opening width smaller than a size of the first trap member 120 when viewed in the direction along the central axis C of the housing 110. The first trap member 120 has a region that overlaps a region surrounding the opening 131 in the second trap member 130 when the first trap member 120 is viewed in the direction along the central axis C of the housing 110. That is, the first trap member 120 and the second trap member 130 overlap each other at an interval in a height direction of the housing 110 in the region surrounding the opening 131 so as to form a labyrinth structure. In FIG. 6, the region of the first trap member 120 overlapping the second trap member 130 is indicated by oblique broken lines. In the first trap member 120, the plurality of openings 122 are formed in the region indicated by the oblique broken lines, and in the second trap member 130, a plurality of openings 132, which do not overlap the plurality of openings 122, are formed in a region facing the region indicated by the oblique broken lines. As a result, the exhaust gas passing through the plurality of openings 122 collides and comes into contact with the top surface of the second trap member 130 on the downstream side and is decelerated. Thus, byproducts contained in the exhaust gas are captured by the top surface of the second trap member 130. In addition, the exhaust gas passing through the plurality of openings 132 collides and comes into contact with the top surface of the first trap member 120 on the downstream side and is decelerated. As a result, the byproducts contained in the exhaust gas are captured by the top surface of the first trap member 120.

The top surfaces of the first trap member 120 and the second trap member 130 may be subjected to surface roughening. Examples of the surface roughening include thermal spraying, blasting, laser processing, or the like. Surface roughening has a function of attaching byproducts. Therefore, by performing the surface roughening on the top surface of each of the first trap member 120 and the second trap member 130, it is possible for the trap apparatus 100 to capture byproducts contained in the exhaust gas through the roughened surface.

As described above, the trap apparatus 100 according to the embodiments have the tubular housing 110, the plate-shaped first trap member 120, and the plate-shaped second trap member 130. The housing 110 has the flow path 113 through which the exhaust gas exhausted through the exhaust pipe 72 flows. The first trap member 120 is arranged in the housing 110 so as to shield the central portion of the flow path 113 when viewed in the direction along the central axis C of the housing 110. The second trap member 130 is arranged at an interval from the first trap member 120 in the housing 110 in the direction along the central axis C of the housing 110, and has openings 131 at positions corresponding to the first trap member 120. As a result, it is possible for the trap apparatus 100 to efficiently capture a target object (i.e., byproducts) contained in the exhaust gas.

In the trap apparatus 100, the opening 131 of the second trap member 130 has an opening width smaller than the size of the first trap member 120 when viewed in the direction along the central axis C of the housing 110. As a result, in the trap apparatus 100, it is possible to sufficiently secure an area of a range of contact in which the second trap member 130 and the exhaust gas collected in the opening 131 come into contact with each other, and thus to further improve the efficiency of capturing the target object in the second trap member 130.

In the trap apparatus 100, the first trap member 120 has the plurality of openings 122 in the region overlapping the region surrounding the opening 131 in the second trap member 130 when viewed in the direction along the central axis C of the housing 110. As a result, it is possible for the trap apparatus 100 to promote the flow of exhaust gas toward the downstream side of the first trap member 120 and to suppress a decrease in the conductance of the flow path 113. In addition, the trap apparatus 100 is provided with the plurality of openings 122 in the region overlapping the region surrounding the opening 131 in the second trap member 130, whereby it is possible to capture the byproducts contained in the exhaust gas passing through the plurality of openings 122 on the top surface of the second trap member 130.

In the trap apparatus 100, the second trap member 130 has the plurality of openings 132, which do not overlap the plurality of openings 122 in the first trap member 120, in the region overlapping the first trap member 120 when viewed in the direction along the central axis C of the housing 110. As a result, it is possible for the trap apparatus 100 to promote the flow of the exhaust gas toward the downstream side of the second trap member 130 and to suppress a decrease in the conductance of the flow path 113. In addition, the trap apparatus 100 is provided with the plurality of openings 132 in the region overlapping the first trap member 120, whereby it is possible to capture the byproducts contained in the exhaust gas passing through the plurality of openings 132 on the top surface of the first trap member 120 on the downstream side.

In addition, the trap apparatus 100 has the plurality of first trap members 120 and the plurality of second trap members 130. The plurality of first trap members 120 and the plurality of second trap members 130 are alternately arranged in the direction along the central axis C of the housing 110. As a result, in the trap apparatus 100, a bent exhaust path between the first trap members 120 and the second trap members 130 is formed in multiple stages. Thus, it is possible to increase a number of collision and contact of the exhaust gas with the top surfaces of the trap members in each stage, and to improve the efficiency of capturing byproducts.

Although embodiments have been described above, it should be considered that the embodiments disclosed herein are illustrative and are not restrictive in all respects. Indeed, the embodiments described above can be implemented in various forms. In addition, the embodiments described above may be omitted, replaced, or modified in various forms without departing from the scope and spirit of the claims.

In the above embodiments, it has been described that the substrate processing apparatus is an apparatus that performs plasma processing such as plasma etching. However, the technique disclosed herein is applicable to any apparatus that performs other plasma processing such as CVD film formation.

According to the present disclosure, it is possible to efficiently capture a target object contained in an exhaust gas.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A trap apparatus comprising:
a tubular housing including a flow path through which an exhaust gas exhausted through an exhaust pipe flows;
a plate-shaped first trap member arranged inside the housing so as to shield a central portion of the flow path when viewed in a direction along a central axis of the housing; and
a plate-shaped second trap member arranged inside the housing at an interval from the first trap member in the direction along the central axis of the housing, the second trap member including an opening at a position corresponding to the first trap member.

2. The trap apparatus of claim 1, wherein the opening in the second trap member has an opening width smaller than a size of the first trap member when viewed from the direction along the central axis of the housing.

3. The trap apparatus of claim 2, wherein the first trap member includes a plurality of openings in a region overlapping a region surrounding the opening in the second trap member when viewed in the direction along the central axis of the housing.

4. The trap apparatus of claim 3, wherein the second trap member includes a plurality of openings, which do not overlap the plurality of openings in the first trap member, in a region overlapping the first trap member when viewed from the direction along the central axis of the housing.

5. The trap apparatus of claim 4, comprising:
a plurality of the first trap members and a plurality of the second trap members, wherein the plurality of the first trap members and the plurality of the second trap members are alternately arranged in the direction along the central axis of the housing.

6. The trap apparatus of claim 1, comprising:
a plurality of the first trap members and a plurality of the second trap members, wherein the plurality of the first trap members and the plurality of the second trap members are alternately arranged in the direction along the central axis of the housing.

7. A substrate processing apparatus comprising:
a processing container in which substrate processing is performed;
an exhaust apparatus configured to exhaust a gas containing a byproduct generated by the substrate processing from the processing container;
an exhaust pipe interconnecting the processing container and the exhaust apparatus; and
a trap apparatus provided in the exhaust pipe and configured to capture the byproduct contained in the gas exhausted from the processing container through the exhaust pipe, wherein the trap apparatus includes:
a tubular housing including a flow path through which the gas exhausted through the exhaust pipe flows;
a plate-shaped first trap member arranged inside the housing so as to shield a central portion of the flow path when viewed in a direction along a central axis of the housing; and
a plate-shaped second trap member arranged inside the housing at an interval from the first trap member in the direction along the central axis of the housing, the second trap member including an opening at a position corresponding to the first trap member.
